(19) United States
(12) Patent Application Publication
(10) Pub. No.: US 2013/0087815 A1
(43) Pub. Date: Apr. 11, 2013

(54) HYBRID DISPLAY DEVICE

(71) Applicants: Jane-Hway Liao, Hsinchu County (TW); Chung-Wen Wu, Hsinchu County (TW); Yu-Hsuan Liao, Taipei City (TW); Chun-Wei Su, New Taipei City (TW)

(72) Inventors: Jane-Hway Liao, Hsinchu County (TW); Chung-Wen Wu, Hsinchu County (TW); Yu-Hsuan Liao, Taipei City (TW); Chun-Wei Su, New Taipei City (TW)

(73) Assignee: Industrial Technology Research Institute, Hsinchu (TW)

(21) Appl. No.: 13/482,982

(22) Filed: May 29, 2012

(30) Foreign Application Priority Data
Oct. 5, 2011 (TW) TW100136021

(51) Int. Cl. H01L 27/15

(52) U.S. Cl. 257/88; 257/E27.121

(57) ABSTRACT

The disclosure provides a hybrid display device, comprising: a substrate, wherein the substrate comprises a first surface and a second surface; a TFT array layer formed on the first surface of the substrate; a first display device formed on the TFT array layer; and a second display device formed on the second surface of the substrate, wherein there exists a corresponding relationship between a dielectric constant (k) of the substrate and a thickness (t) of the substrate to drive at least one of the first display device and the second display device, or to drive both of the first display device and the second display device by the TFT array layer, especially the TFT array layer actively drive the first display device, the second display device or combinations thereof. The dielectric constant of the substrate is about 1-100 and the thickness of the substrate is about 0.1-60 μm.

### CROSS REFERENCE TO RELATED APPLICATIONS

This Application claims priority of Taiwan Patent Application No. 100136021, filed on Oct. 5, 2011, the entirety of which is incorporated by reference herein.

### BACKGROUND

1. Field of the Disclosure

The present disclosure relates to a hybrid display device, and in particular relates to a hybrid display device with a single thin film transistor (TFT) substrate.

2. Description of the Related Art

As technology advances, a variety of displays have been widely used in many electronic products. When a consumer wants to play the still images and text, an e-paper (electronic paper) with low power consumption may be chosen. When the consumer wants to play dynamic video, an organic light emitting diode (OLED) with high chrominance and high response time may be chosen. However, a single display may not simultaneously meet the requirements of high chrominance and low power consumption. Thus, a hybrid display device integrating two displays has been developed.

Currently, a conventional hybrid display device is formed by assembling two different displays by an adhesive. However, two thin film transistors (TFTs) and two substrates are needed to separately drive the two displays. Thus, the total thickness of the hybrid display device is limited. Additionally, integrating of two fabrication processes is another challenge.

### BRIEF SUMMARY

The disclosure provides a hybrid display device, comprising: a substrate, wherein the substrate comprises a first surface and a second surface; a thin film transistor (TFT) array layer formed on the first surface of the substrate; a first display device formed on the TFT array layer; and a second display device formed on the second surface of the substrate, wherein there exists a corresponding relationship between a dielectric constant (k) of the substrate and a thickness (t) of the substrate to drive at least one of the first display device and the second display device or both the first display device and the second display device by the TFT array layer, and the dielectric constant of the substrate is about 1-100 and the thickness of the substrate is about 0.1-60 μm.

The disclosure also provides a hybrid display device, comprising: a substrate, wherein the substrate comprises a first surface and a second surface; a thin film transistor (TFT) array layer formed on the first surface of the substrate; a first display device formed on the TFT array layer; and a second display device formed on the second surface of the substrate, wherein at least one of the first display device and the second display device or both of the first display device and the second display device are driven by the TFT array layer, and the first display device is a current-driven display device or a voltage-driven display device, and the second display device is a voltage-driven display device.

A detailed description is given in the following embodiments with reference to the accompanying drawings.

### BRIEF DESCRIPTION OF THE DRAWING

For a more complete understanding of the present disclosure, reference is now made to the following descriptions taken in conjunction with the accompanying drawings, in which:

FIG. 1 shows a cross-sectional schematic representation of a hybrid display device in accordance with an embodiment of the disclosure;

FIG. 2 shows a cross-sectional schematic representation of a simulated display device in accordance with an embodiment of the disclosure;

FIGS. 3A-3B show the cross-sectional schematic representations of a hybrid display device in accordance with an embodiment of the disclosure;

FIGS. 4A-4H show the cross-sectional schematic representations of the method for fabricating the hybrid display device in accordance with an embodiment of the disclosure; and

FIG. 5 shows a relationship of a driving voltage, a dielectric constant of the substrate and a thickness of the substrate to define a corresponding relationship between a dielectric constant (k) of the substrate and a thickness (t) of the substrate of the disclosure.

### DETAILED DESCRIPTION

There is a need to develop a hybrid display device with a single TFT substrate. The single TFT substrate is shared by two display devices to actively drive the two display devices. Thus, the thickness of the hybrid display device may be reduced and the fabricating process and cost may also be reduced.

The following description is of the embodiment of carrying out the disclosure. This description is made for the purpose of illustrating the general principles of the disclosure and should not be taken in a limiting sense. The scope of the disclosure is best determined by reference to the appended claims.

One embodiment of the disclosure provides a hybrid display device which has two displays and one thin film transistor (TFT) array layer. The single TFT array layer is shared by two display devices to drive the two display devices, especially to actively drive the two display devices.

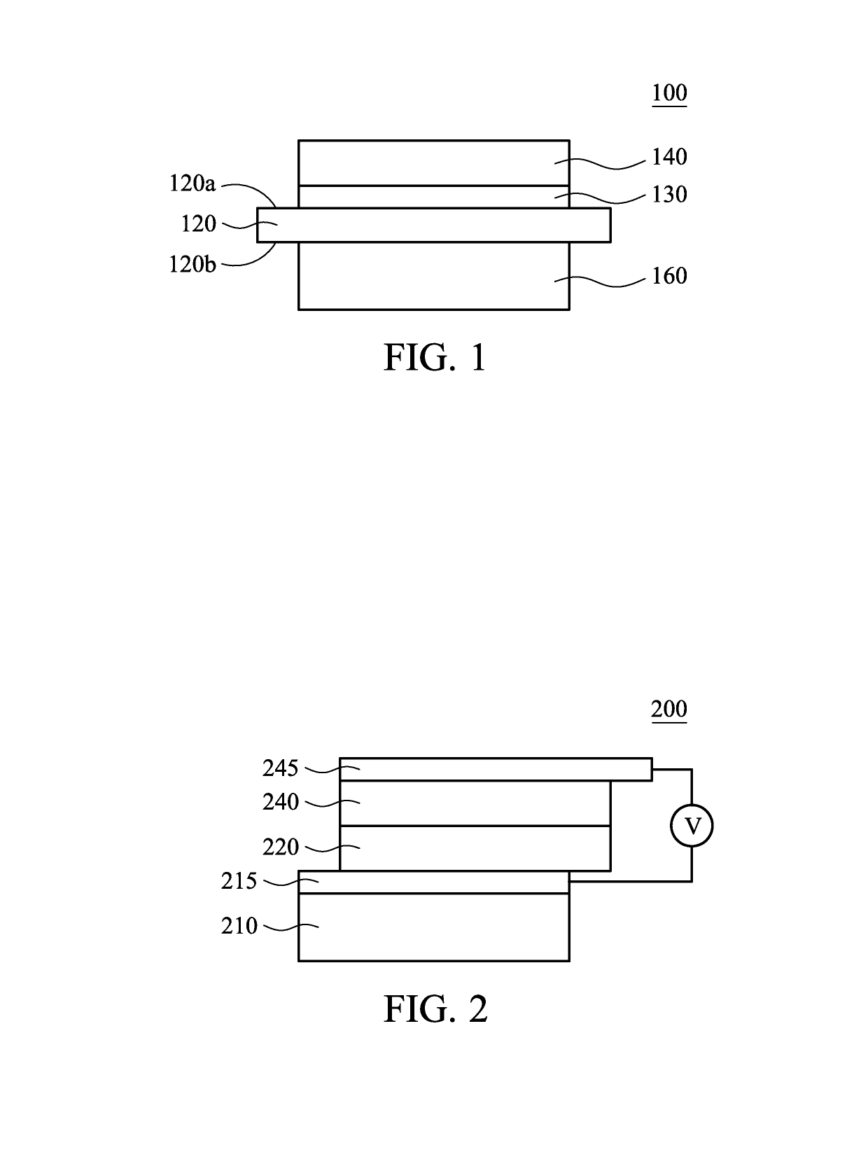

Referring to FIG. 1, a hybrid display device 100 comprises: a substrate 120, wherein the substrate 120 comprises a first surface 120a and a second surface 120b. A thin film transistor (TFT) array layer 130 and a first display device 140 are sequentially formed on the first surface 120a of the substrate 120; and a second display device 160 formed on the second surface 120b of the substrate 120.

The first display device 140 may be a current-driven display device or a voltage-driven display device, and the second display device 160 may be a voltage-driven display device. The current-driven display device comprises an organic light emitting diode (OLED) or polymer light emitting device (PLED). The voltage-driven display device comprises a liquid crystal display (LCD), cholesteric liquid crystal display (Ch-LCD) or electro-fluidics display (EFD). The EFD comprises an electrowetting display (EWD), electrophoretic display (EPD), electrokinetic display (EKD) or quick response liquid powder display (QR-LPD).

The TFT array layer 130 may be a top gate structure or a bottom gate structure. The TFT may be an organic thin film transistor (OTFT), low temperature poly silicon TFTs, metal oxide TFTs, amorphous silicon TFTs, micro-crystalline silicon TFTs, polycrystalline silicon TFTs, single crystal silicon TFTs or oxide TFTs.

In one embodiment, at least one of the first display device 140 and the second display device 160 is actively driven by the single TFT array layer 130 on different sides of the substrate 220. In another embodiment, both of the first display device 140 and the second display device 160 are actively driven by the single TFT array layer 130 on different sides of the substrate 220. In one embodiment, the first display device 140 or the second display device 160 is independently driven by the single TFT array layer 130. In another embodiment, the first display device 140 and the second display device 160 are simultaneously driven by the single TFT array layer 130. The second display device 160 is located on the back side of the TFT array layer 130, and thus the substrate 120 is formed between the second display device 160 and the TFT array layer 130. The second display device 160 is driven by the TFT array layer 130 by crossing the substrate 120, resulting in an inevitable cross voltage. However, a high cross voltage may cause high power consumption and damage display devices. Thus, a corresponding relationship between a dielectric constant (k) of the substrate and a thickness (t) of the substrate has been defined to avoid the cross voltage problem. The corresponding relationship is that the dielectric constant (k) of the substrate 120 increases along with an increase in the thickness (t) range of the substrate 120. The dielectric constant (k) of the substrate 120 is about 1-100 and the thickness (t) of the substrate 120 is about 0.1-60 μm.

In one embodiment, FIG. 2 shows a cross-sectional schematic representation of a simulated display device 200. A first electrode 215, a substrate 220, a display device 240 and a second electrode 245 are sequentially formed on a supporting substrate 210. The substrate 220 is made by a variety of materials having different dielectric constants (k) and thicknesses (t). The required driving voltage (V) is acquired by measuring the voltage between the first electrode 215 and the second electrode 245 on different sides of substrate 220.

According to the experiments and statistical analysis, the driving voltage, the different dielectric constant (k) of the substrate 220 and the thickness (t) of the substrate 220 have a following relationship:

Driving voltage (V)=1/(−0.0074+0.0523 k−0.00808 t)

wherein the dielectric constant (k) of the substrate 220 is about 1-100 and the thickness (t) of the substrate 220 is about 0.1-60 μm.

The experimental data shows that if a constant voltage is applied and the dielectric constant (k) of the substrate 220 is large, the thickness (t) of the substrate 220 can be chosen in a wider range. In other words, if a constant voltage is applied and the dielectric constant (k) of the substrate 220 is small, the thickness (t) of the substrate 220 can only be chosen in a limited range.

Table 1 shows the relationship between the dielectric constant (k) and the thickness (t) of Example 1-Example 8.

TABLE 1

| | dielectric | |
|---|---|---|
| Example | constant (k) | thickness (t) |
| Example 1 | 1-5 | about 0.1-3.5 μm |
| Example 1 | 5-10 | about 0.1-14 μm |
| Example 3 | 10-15 | about 0.1-20 μm |
| Example 4 | 15-20 | about 0.1-25 μm |
| Example 5 | 20-30 | about 0.1-33 μm |
| Example 6 | 30-40 | about 0.1-45 μm |
| Example 7 | 40-50 | about 0.1-55 μm |
| Example 8 | 50-100 | about 0.1-60 μm |

Referring to FIG. 1 again, the material of the substrate 120 comprises an organic material, inorganic material or combinations thereof. The organic material may be polymer, nano-polymer or temperature sensitive polymer, such as polyvinylidene fluoride (PVDF), polyimide (PI) or combinations thereof.

The inorganic material may be glass material, ceramic material, nano-inorganic material or metal material, such as SiₓO_{y}, SiₓN_{y}, Al₂O₃, Ta₂O₅, TiO₂, or BaₓSr₁₋ₓTiO₃ (Barium Strontium Titanate, BST).

Besides the above-mentioned materials, other materials mixing organic and inorganic material may also be included in the scope of the disclosure. The material of the substrate 120 may be a semiconductor material, a uniform material or non-uniform material, a transparent, semi-transparent or non-transparent material. Only the dielectric constant (k) of the substrate meet the required values, and the materials of the substrate are not limited the above-mentioned materials.

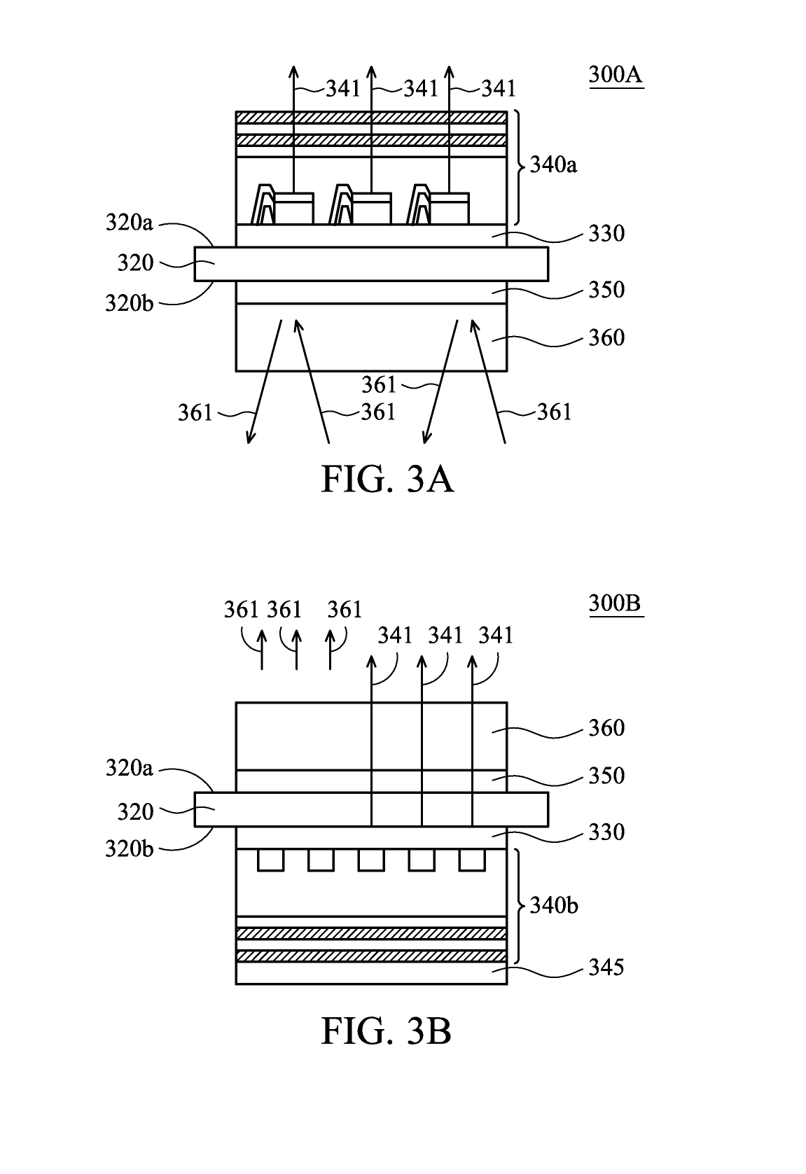

FIG. 3A shows another embodiment of the hybrid display device 300A, which comprises a substrate 320, and the substrate 320 comprises a first surface 320a and a second surface 320b. A thin film transistor array layer 330 is formed on the first surface 320a of the substrate 320. A top emission organic light emitting diode (Top emission OLED) 340a is formed on the thin film transistor array layer 330.

An electro-fluidics display (EFD) 360 is formed on the second surface 320b of the substrate 320. An adhesion layer 350 is formed between the substrate 320 and the electro-fluidics display (EFD) 360 to adhere to both.

In this embodiment, the observer is located in the front of the first surface 320a of the substrate 320 to observe the light 341 emitted from the top emission organic light emitting diode (Top emission OLED) 340a. Furthermore, the observer is located in the front of the second surface 320b of the substrate 320 to observe the light 361 emitted from the electro-fluidics display (EFD) 360.

In the embodiment, the observer may be located at different positions to observe the hybrid display device, such as in front of the first surface 320a or the second surface 320b of the substrate 320.

FIG. 3B shows another embodiment of the hybrid display device 300B, which comprises a substrate 320, and the substrate 320 comprises a first surface 320a and a second surface 320b. A thin film transistor array layer 330 is formed on the first surface 320a of the substrate 320. A bottom emission organic light emitting diode (Bottom emission OLED) 340b is formed on the thin film transistor array layer 330. An encapsulation layer 345 is formed on the bottom emission organic light emitting diode (Bottom emission OLED) 340b.

An electro-fluidics display (EFD) 360 is formed on the first surface 320a of the substrate 320. An adhesion layer 350 is formed between the substrate 320 and the electro-fluidics display (EFD) 360 to adhere to both.

In FIG. 3B, the observer is located at the front of the first surface 320a of the substrate 320 to observe the light 341 emitted from the bottom emission organic light emitting diode (Bottom emission OLED) 340b. Furthermore, the observer is located at the front of the second surface 320b of the substrate 320 to observe the light 361 emitted from the electro-fluidics display (EFD) 360. The feature of the embodiment is that when the observation is during the daytime or conducted under a sufficiently bright environment, the electro-fluidics display (EFD) 360 is driven by the thin film transistor array layer 330 to reflect the light 361. When the observation is during the night or conducted under a weak light environment, the bottom emission organic light emitting diode (Bottom emission OLED) 340b is driven by the thin film transistor array layer 330 to emit the light 341. Thus, no matter what brightness the environment light is, the hybrid display device 300B may be used.

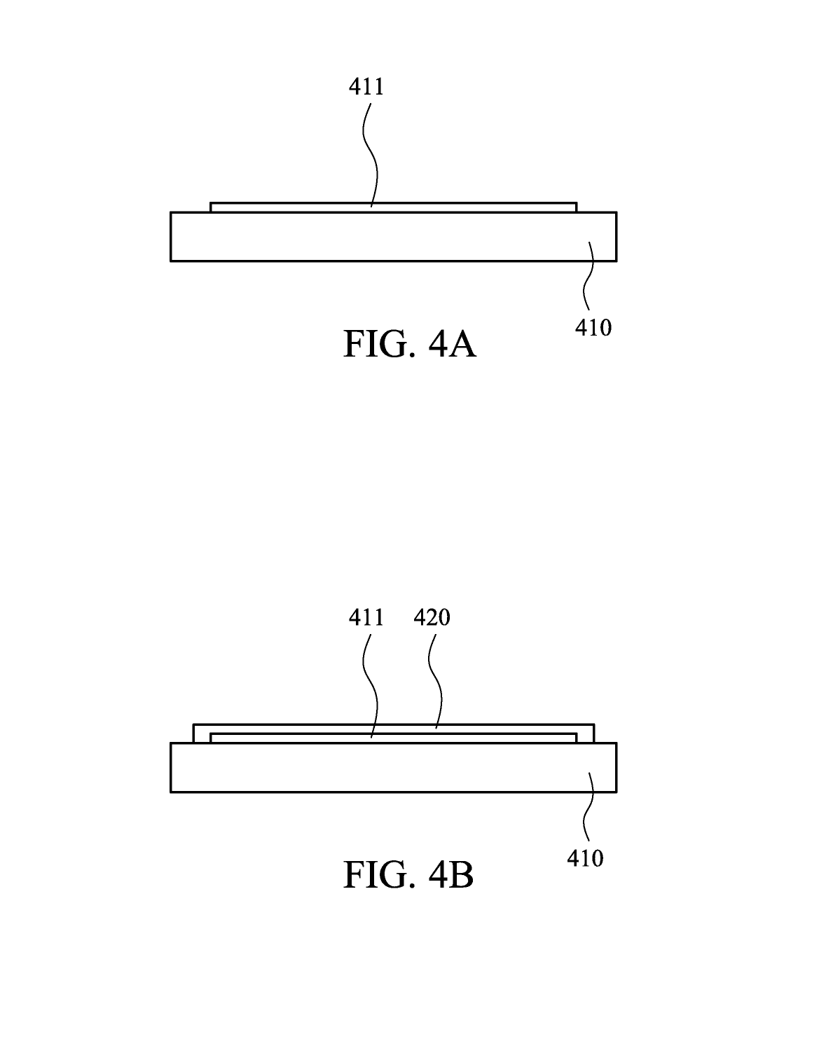

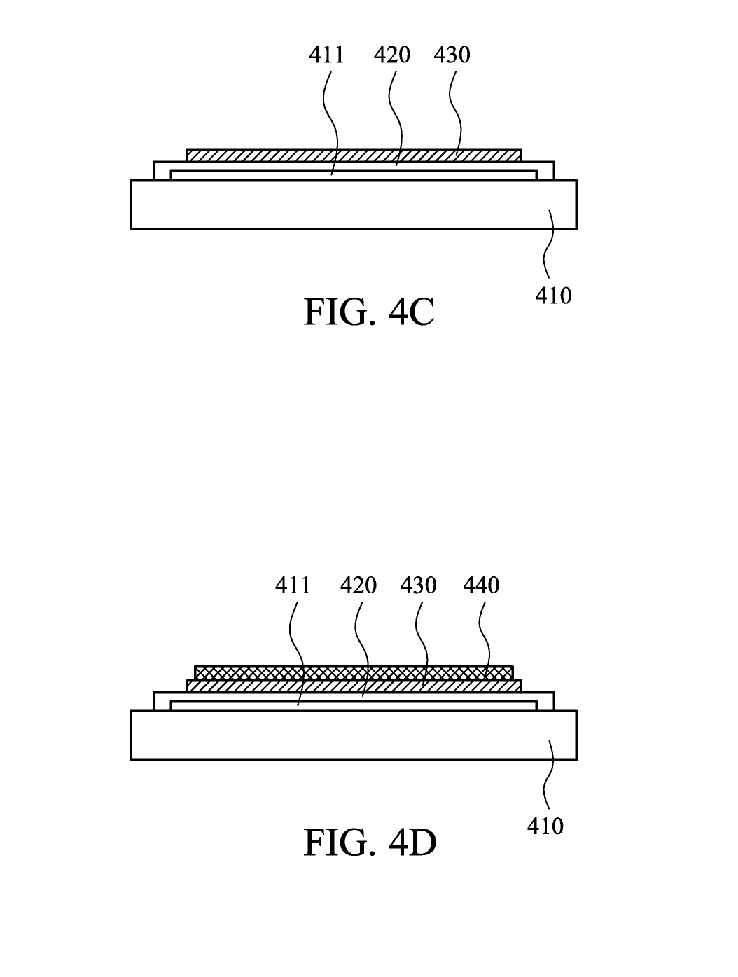

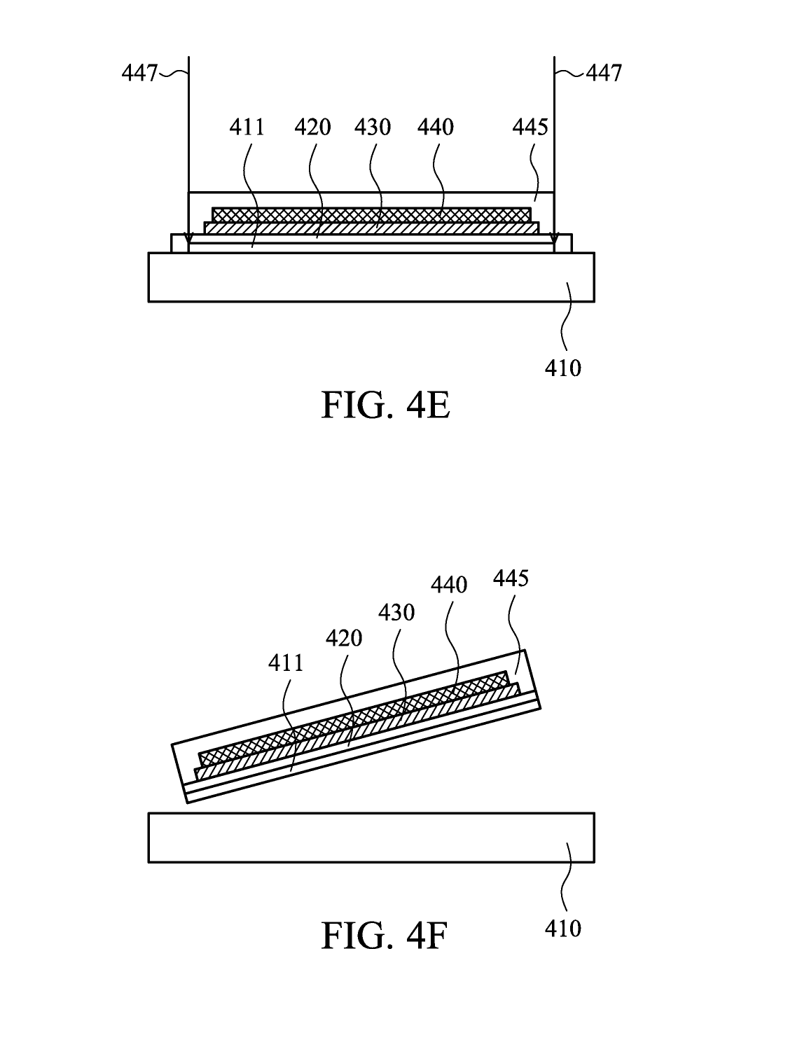

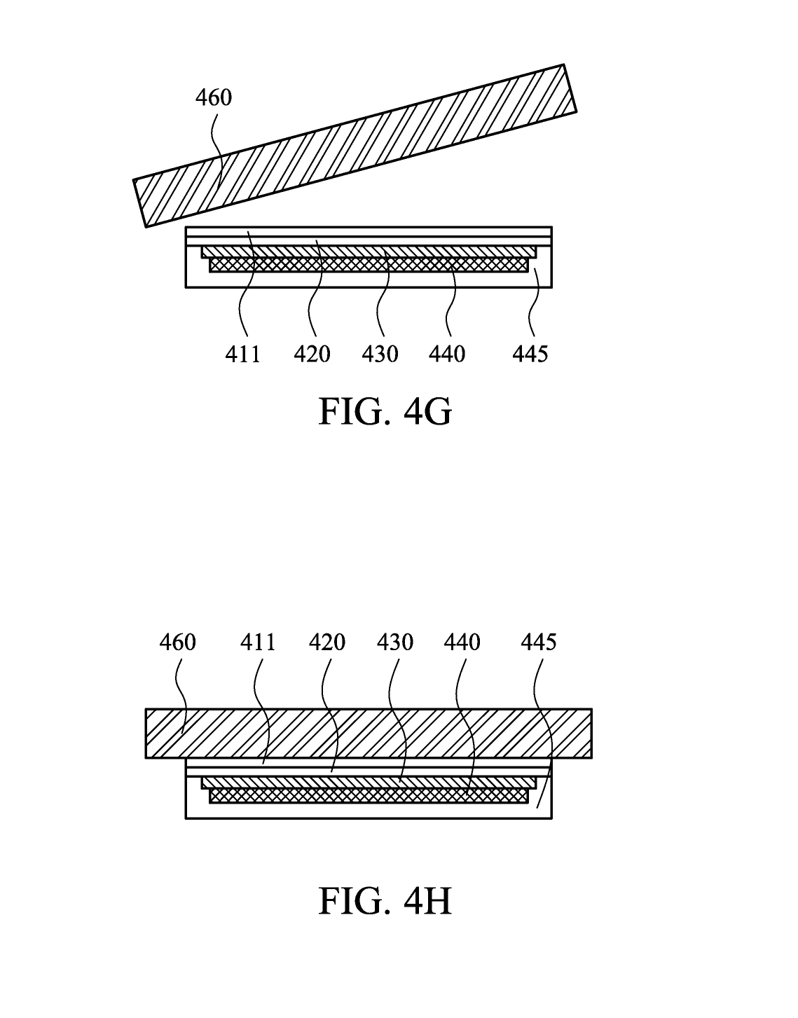

Referring to FIG. 4A-4H, the disclosure also provides a method for fabricating the hybrid display device. In FIG. 4A, a temporal substrate 410 is provided, such as glass. Then, a release layer 411 is formed on the temporal substrate 410.

In FIG. 4B, a substrate 420 is formed on the release layer 411. The substrate 420 will be shared by the lateral two display devices. The substrate 420 is formed by a coating method, evaporation method or sputter method.

There exists a corresponding relationship between a dielectric constant (k) of the substrate 420 and a thickness (t) of the substrate 420 for driving the two display devices, especially to actively drive the two display devices. The dielectric constant of the substrate 420 is about 1-100 and the thickness of the substrate 420 is about 0.1-60 μm.

Referring to FIG. 4C, a thin film transistor layer 430 is formed on the substrate 420. The thin film transistor layer 430 is used to drive the two display devices, especially to actively drive the two display devices.

Referring to FIG. 4D, a first display media 440 is formed on the thin film transistor layer 430, and the first display media 440 comprises a current-driven display device or voltage-driven display device. In one embodiment, the first display media is an organic light emitting device (OLED) which comprises an electron injection layer, electron transporting layer, light emitting layer, hole transporting layer and hole injection layer.

Referring to FIG. 4E, an encapsulation layer 445 is formed on the temporal substrate 410 to cover and protect the first display media 440. Then, a first cutting step 447 is performed to the release layer 411 along the cutting line, and the size of the cutting line is less than the size of the release layer 411. A portion of the substrate 420 and the encapsulation layer 445 are removed. The thin film transistor layer 430 and the first display media 440 must be covered completely by the encapsulation layer 445 to resist moisture. Additionally, the size of the encapsulation layer 445 is irrelevant to the size of the release layer 411 and the size of the cutting lines of the first cutting step 447.

Referring to FIG. 4F, the temporal substrate 410 is removed to expose the release layer 411 and the substrate 420.

Referring to FIG. 4G, a second display device 460 is adhered to the exposed release layer 411 and the exposed substrate 420. The second display device 460 is a voltage-driven display device. In one embodiment, the second display device 460 comprises an electrophoretic display (EPD).

Referring to FIG. 4H, the first display media 440 and the second display device 460 are driven by the single thin film transistor layer 430, especially are actively driven by the single thin film transistor layer 430.

From the above description, the two display devices may be driven by a single thin film transistor layer, especially may be actively driven by the single thin film transistor layer 430, by selecting an adequate dielectric constant (k) and thickness (t) of the substrate. Therefore, the thickness of the hybrid display device is reduced and the fabricating process and cost are also reduced.

### EXAMPLE

Referring to FIG. 2 again, the supporting substrate 210 was glass, and the first electrode 215 and the second electrode 245 were transparent indium tin oxide glass (ITO glass). The display device 240 was electrophoretic display (EPD). A variety of substrates 220 having different dielectric constants (k) of about 3, 4.3, 5.1, 5.33, 5.88, 6.03, 6.19, 6.45, 6.94, 7 and different thicknesses was used.

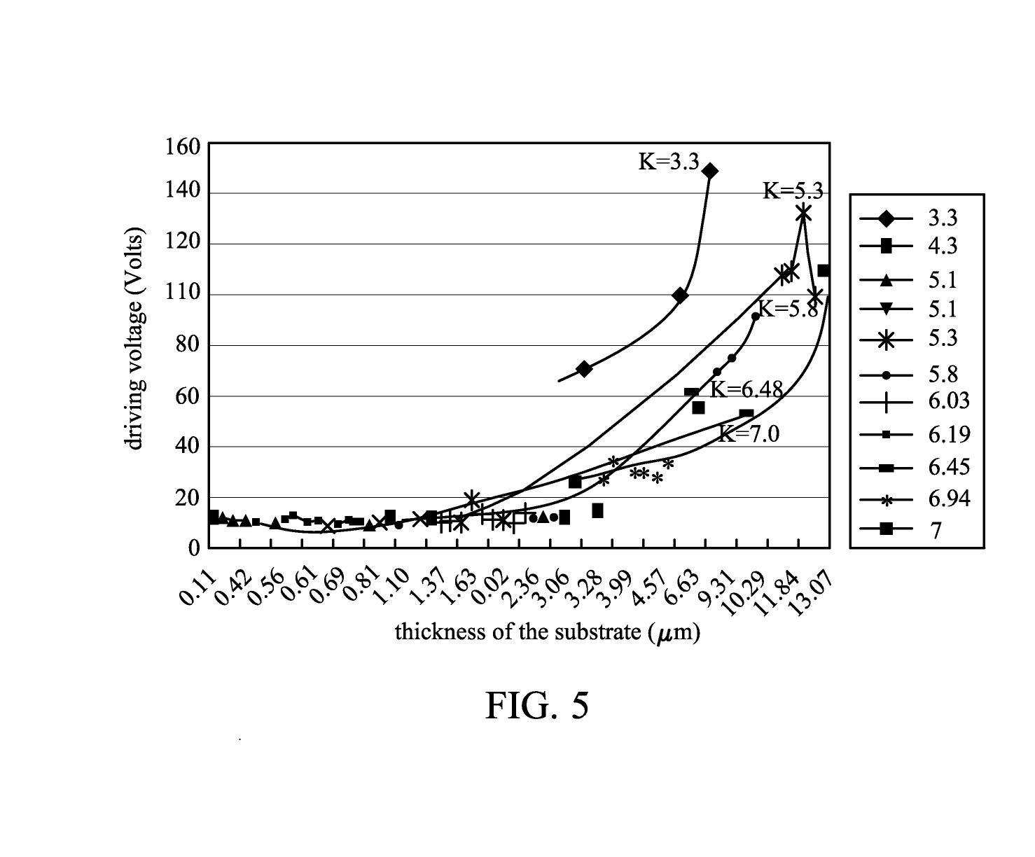

FIG. 5 shows a relationship of a driving voltage, a dielectric constant of the substrate and a thickness of the substrate. As shown in FIG. 5, the thickness (t) range of the substrate 220 increases along with an increase in the dielectric constant (k) of the substrate 220.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A hybrid display device, comprising:
a substrate, wherein the substrate comprises a first surface and a second surface;
a thin film transistor (TFT) array layer formed on the first surface of the substrate;
a first display device formed on the TFT array layer; and
a second display device formed on the second surface of the substrate, wherein there exists a corresponding relationship between a dielectric constant (k) of the substrate and a thickness (t) of the substrate for driving at least one of the first display device and the second display device by the TFT array layer, and the dielectric constant of the substrate is about 1-100 and the thickness of the substrate is about 0.1-60 μm.

2. The hybrid display device as claimed in claim 1, wherein the corresponding relationship is that the dielectric constant (k) of the substrate increases along with an increase in the thickness (t) range of the substrate.

3. The hybrid display device as claimed in claim 1, wherein both of the first display device and the second display device are driven by the TFT array layer.

4. The hybrid display device as claimed in claim 1, wherein at least one of the first display device and the second display device is actively driven by the TFT array layer.

5. The hybrid display device as claimed in claim 3, wherein both of the first display device and the second display device are actively driven by the TFT array layer.

6. The hybrid display device as claimed in claim 1, wherein the dielectric constant (k) of the substrate in a range of about 1-5 corresponds to the thickness (t) of the substrate in a range of about 0.1-3.5 μm.

7. The hybrid display device as claimed in claim 1, wherein the dielectric constant (k) of the substrate in a range of about 5-10 corresponds to the thickness (t) of the substrate in a range of about 0.1-14 μm.

8. The hybrid display device as claimed in claim 1, wherein the dielectric constant (k) of the substrate in a range of about 10-15 corresponds to the thickness (t) of the substrate in a range of about 0.1-20 μm.

9. The hybrid display device as claimed in claim 1, wherein the dielectric constant (k) of the substrate in a range of about 15-20 corresponds to the thickness (t) of the substrate in a range of about 0.1-25 μm.

10. The hybrid display device as claimed in claim 1, wherein the dielectric constant (k) of the substrate in a range of about 20-30 corresponds to the thickness (t) of the substrate in a range of about 0.1-33 μm.

11. The hybrid display device as claimed in claim 1, wherein the dielectric constant (k) of the substrate in a range of about 30-40 corresponds to the thickness (t) of the substrate in a range of about 0.1-45 μm.

12. The hybrid display device as claimed in claim 1, wherein the dielectric constant (k) of the substrate in a range of about 40-50 corresponds to the thickness (t) of the substrate in a range of about 0.1-55 μm.

13. The hybrid display device as claimed in claim 1, wherein the dielectric constant (k) of the substrate in a range of about 50-100 corresponds to the thickness (t) of the substrate in a range of about 0.1-60 μm.

14. The hybrid display device as claimed in claim 1, wherein the first display device is a current-driven display device or a voltage-driven display device, and the second display device is a voltage-driven display device.

15. The hybrid display device as claimed in claim 1, wherein the material of the substrate comprises an organic material, inorganic material or combinations thereof.

16. A hybrid display device, comprising:
a substrate, wherein the substrate comprises a first surface and a second surface;
a thin film transistor (TFT) array layer formed on the first surface of the substrate;
a first display device formed on the TFT array layer; and
a second display device formed on the second surface of the substrate, wherein at least one of the first display device and the second display device are driven by the TFT array layer, and the first display device is a current-driven display device or a voltage-driven display device, and the second display device is a voltage-driven display device.

17. The hybrid display device as claimed in claim 16, wherein the current-driven display device comprises an organic light emitting diode (OLED) or polymer light emitting diode (PLED).

18. The hybrid display device as claimed in claim 16, wherein the voltage-driven display device comprises a liquid crystal display (LCD), cholesteric liquid crystal display (Ch-LCD), electrowetting display (EWD), electrophoretic display (EPD), electrokinetic display (EKD) or quick response liquid powder display (QR-LPD).

19. The hybrid display device as claimed in claim 16, wherein a dielectric constant (k) of the substrate is about 1-100 and a thickness (t) of the substrate is about 0.1-60 μm.

20. The hybrid display device as claimed in claim 16, wherein both of the first display device and the second display device are driven by the TFT array layer.

21. The hybrid display device as claimed in claim 16, wherein at least one of the first display device and the second display device is actively driven by the TFT array layer.

22. The hybrid display device as claimed in claim 20, wherein both of the first display device and the second display device are actively driven by the TFT array layer.

23. The hybrid display device as claimed in claim 16, wherein the material of the substrate comprises an organic material, inorganic material or combinations thereof.
